(19) United States
(12) Patent Application Publication
(10) Pub. No.: US 2025/0156612 A1
(43) Pub. Date: May 15, 2025

(54) SIMULATION METHOD AND SYSTEM OF JOINT EXPLOITATION OF NATURAL GAS HYDRATE, SHALLOW GAS AND DEEP-SEATED GAS

(71) Applicant: China University of Petroleum (East China), Qingdao City (CN)

(72) Inventors: Jianchun XU, Qingdao City (CN); Caojie LI, Qingdao City (CN); Shuxia LI, Qingdao City (CN); Shuyang LIU, Qingdao City (CN); Xiaopu WANG, Qingdao City (CN)

(21) Appl. No.: 18/949,193

(22) Filed: Nov. 15, 2024

(30) Foreign Application Priority Data
Nov. 15, 2023 (CN) 202311515925.5

(51) Int. Cl. G06F 30/28; E21B 41/00

(52) U.S. Cl. CPC G06F 30/28; E21B 41/0099; E21B 2200/20

(57) ABSTRACT

Provided is a simulation method and system of joint exploitation of natural gas hydrate, shallow gas and deep-seated gas. The method includes: constructing a simulation model of joint exploitation of a shallow gas layer and a hydrate layer, including setting and meshing the shallow gas layer and the hydrate layer, constructing the simulation model of joint exploitation by setting a formation parameter and a production parameter, and solving the model to acquire productivity data; constructing a simulation model of joint exploitation of the shallow gas layer, the deep-seated gas layer and the hydrate layer, including setting and meshing the shallow gas layer, the deep-seated gas layer and the hydrate layer, constructing a simulation model of joint exploitation of the shallow gas layer, the deep-seated gas layer and the hydrate layer by setting the formation parameter and the production parameter, and solving the model to acquire productivity data.

### CROSS-REFERENCE TO RELATED APPLICATION

This patent application claims the benefit and priority of Chinese Patent Application No. 202311515925.5 filed with the China National Intellectual Property Administration on Nov. 15, 2023, the disclosure of which is incorporated by reference herein in its entirety as part of the present application.

### TECHNICAL FIELD

The present disclosure relates to the technical field of natural gas hydrate exploitation, in particular to a simulation method and system of joint exploitation of natural gas hydrate, shallow gas and deep-seated gas.

### BACKGROUND

With the development of economy and the advancement of society, the demand for energy is increasing gradually. Energy Information Administration reported in the International Energy Outlook 2019 that the world energy consumption will increase by nearly 50% between 2018 and 2050. With the decrease of conventional fossil fuel reserves, it is imperative to explore and develop unconventional petroleum resources. As an important part of unconventional energy, natural gas hydrate has attracted worldwide attention and research. Compared with other traditional fossil energy, natural gas hydrate is a new type of clean burning fossil energy, which produces less CO₂. In addition, the total carbon content in natural gas hydrate is twice that of traditional fossil energy.

Natural gas hydrate is an ice-like crystalline substance formed by chemical reaction between natural gas and water at a low temperature and at a high pressure, which is commonly known as combustible ice. Natural gas hydrate is an unconventional and clean natural gas resource with a wide distribution and a large number of resources. Under standard temperature and pressure, 1 m³ of natural gas hydrate decomposes to produce 164 m³ of natural gas and 0.8 m³ of water.

China is rich in natural gas hydrate reserves, but it is still in the stage of laboratory simulation and geological investigation, mainly because of the lack of understanding of natural gas hydrate exploration and development and the lack in exploitation of on-site commercial system. The numerical simulation technology of a hydrate reservoir is an effective evaluation method. In view of the fact that the research on the simulation of hydrate exploitation is not comprehensive enough at present, and there is a lack of systematic research on the related dynamics exploitation law and the related exploitation schemes of multi-gas joint exploitation, it is necessary to systematically study the exploitation methods of various hydrate reservoirs, analyze their exploitation laws, clarify the characteristic laws of multi-gas joint exploitation, and determine the best exploitation parameters, thus providing scientific basis for multi-gas joint exploitation.

The numerical simulation technology is one of the key technologies to study natural gas hydrate reservoirs. Through the numerical simulation technology, the recovery ratio of various exploitation methods can be predicted and reasonably developed and designed. At the same time, through numerical simulation, each parameter of hydrate can be analyzed, so that the dynamic characteristics of hydrate can be re-recognized, thus providing a basis for future development and utilization.

Therefore, it is urgent to study a simulation method and system of joint exploitation of natural gas hydrate, shallow gas and deep-seated gas.

### SUMMARY

In order to solve the above technical problems, the present disclosure discloses a simulation method and system of joint exploitation of natural gas hydrate, shallow gas and deep-seated gas, which can clarify the characteristics of multi-gas joint exploitation and solve the problems that the daily gas production is low and the stable production time is short in pilot production. Based on an interaction mechanism of a seepage field, a temperature field and a mechanical field, the method carries out three-field coupled flow simulation, and establishes a characterization method of physical property parameters such as a porosity, a permeability, a saturation and a capillary force of a natural gas hydrate reservoir, so that the time-varying law and evolution characteristics of physical property parameters of multi-gas joint exploitation reservoirs can be effectively clarified, and the changing law of physical property parameters of reservoirs in different exploitation stages can be clearly defined.

In order to achieve the above purpose, the present disclosure uses the following technical scheme.

A first aspect of the present disclosure provides a simulation method of joint exploitation of natural gas hydrate, shallow gas and deep-seated gas, including the following steps:
S1, constructing a simulation model of joint exploitation of a shallow gas layer and a hydrate layer, including setting and meshing the shallow gas layer and the hydrate layer, setting a geological parameter, a production parameter and a well control parameter, etc., constructing the simulation model of joint exploitation, and solving the model to acquire productivity data;
S2, on basis of Step S1, adding a deep-seated gas layer below the hydrate layer, meshing the deep-seated gas layer, setting the geological parameter and the production parameter, etc., and then constructing a simulation model of joint exploitation of the shallow gas layer, the deep-seated gas layer and the hydrate layer, and solving the simulation model of joint exploitation of the shallow gas layer, the deep-seated gas layer and the hydrate layer to acquire the productivity data.

In an embodiment, in Step S1, a hydrate decomposition kinetic equation is:

CH₄·NₕH₂O [symbol] CH_{4(g)}+NₕH₂O₍₁₎;
where Nₕ is the number of water molecules bound by hydrate.

The hydrate layer follows a mass conservation equation and an energy conservation equation, and a system conservation relationship is expressed as:

$$\frac{\partial {M}^{κ}}{\partial t} + ∇ \cdot {F}^{κ} = {q}^{κ} ;$$

where t is time in unit of s; κ is a component identifier, and in the system conservation relationship, k represents a hydrate component h, a methane component m, a water component w or energy e; M^{κ} is a sum of all components of κ in unit of kg/m³ or J/m³; F^{κ} is a flowable component of κ in unit of kg/(m²·s); q^{κ} is a source and sink of κ in unit of kg/(m³·s) or J/(m³·s).

The mass conservation equation of the hydrate component is:

$${M}^{h} = ϕ {S}_{H} {ρ}_{H} ;$$

where M^{h} is a sum of a mass of the hydrate component in unit of kg/m³; S_{H} is a saturation of a hydrate phase; ρ_{H} is a density of the hydrate phase in unit of kg/m³.

The mass conservation equation of the methane component is:

$$\begin{matrix}{M}^{m} = ϕ {S}_{A} {ρ}_{A} {X}_{A}^{m} + ϕ {S}_{G} {ρ}_{G} {X}_{G}^{m} + ϕ {S}_{H} {ρ}_{H} {X}_{H}^{m} ; \\ {F}^{m} = {X}_{A}^{m} {F}_{A} + {X}_{G}^{m} {F}_{G} ; \\ {q}^{m} = {X}_{q , A}^{m} {q}_{A} + {X}_{q , G}^{m} {q}_{G} ;\end{matrix}$$

where M^{m} is a sum of a mass of the methane component in unit of kg/m³; ϕ is a porosity of a reservoir; S_{A} is a saturation of a water phase; S_{G} is a saturation of a gas phase; ρ_{A} is a density of the water phase in unit of kg/m³; ρ_{G} is a density of the gas phase in unit of kg/m³; X_{A}^{m} is a ratio of the mass of the methane component to a mass of the water phase; X_{G}^{m} is a ratio of the mass of the methane component to a mass of the gas phase; X_{H}^{m} is a ratio of the mass of the methane component to a mass of the hydrate phase; F_{A} is a mass flow of the water phase passing through per unit cross-sectional area in unit of kg/(m²·s); F_{G} is a mass flow of the gas phase passing through per unit cross-sectional area in unit of kg/(m²·s); F^{m} is a mass flow of the methane component passing through per unit cross-sectional area in unit of kg/(m²·s); q^{m} is a source and sink of the methane component in unit of kg/(m³·s); q_{A} is a source and sink of the water phase in unit of kg/(m³·s); q_{G} is a source and sink of the gas phase in unit of kg/(m³·s); X_{q,A}^{m} is a ratio of the mass of the methane component to a mass of the source and sink of the water phase; X_{q,G}^{m} is a ratio of the mass of the methane component to a mass of the source and sink of the gas phase.

The mass conservation equation of the water component is:

$$\begin{matrix}{M}^{w} = ϕ {S}_{A} {ρ}_{A} {X}_{A}^{w} + ϕ {S}_{G} {ρ}_{G} {X}_{G}^{w} + ϕ {S}_{H} {ρ}_{H} {X}_{H}^{w} ; \\ {F}^{w} = {X}_{A}^{w} {F}_{A} + {X}_{G}^{w} {F}_{G} ; \\ {q}^{w} = {X}_{q , A}^{w} {q}_{A} + {X}_{q , G}^{w} {q}_{G} ;\end{matrix}$$

where M^{w} is a sum of a mass of the water component in unit of kg/m³; X_{A}^{w} is a ratio of the mass of the water component to the mass of the water phase; X_{G}^{w} is a ratio of the mass of the water component to the mass of the gas phase; X_{H}^{w} is a ratio of the mass of the water component to the mass of the hydrate phase; F^{w} is a mass flow of the water component passing through per unit cross-sectional area in unit of kg/(m²·s); q^{w} is a source and sink of the water component in unit of kg/(m³·s); X_{q,A}^{w} is a ratio of the mass of the water component to the mass of the source and sink of the water phase; X_{q,G}^{w} is a ratio of the mass of the water component to a mass in the source and sink of the gas phase.

The energy conservation equation is:

$$\begin{matrix}{M}^{e} = ( 1 - ϕ ) {ρ}_{A} {H}_{R} + {\sum }_{β = A , G , H} ϕ {s}_{β} {ρ}_{β} {H}_{β} + ϕ {ρ}_{H} Δ {s}_{H} Δ {H}_{0} ; \\ {F}^{e} = - {K}_{c} ∇ T + {\sum }_{β = A , G} {H}_{β} {F}_{β} ; \\ {q}^{e} = {\sum }_{β = A , G} {H}_{β} {q}_{β} ;\end{matrix}$$

where M^{e} is a sum of energy in unit of J/m³; ρ_{R} is a density of rock in unit of kg/m³; H_{R} is an enthalpy of rock in unit of J/kg; s_{β} is a saturation of β phase; H_{β} is an enthalpy of β phase in unit of J/kg; Δs_{H} is a change value of a hydrate saturation in current time step; ΔH₀ is decomposition/formation enthalpy of hydrate in unit of J/kg; F^{e} is energy flow rate in unit of J/(m²·s); K_{c} is a comprehensive thermal conductivity of the system in unit of W/(m·K); F_{β} is the mass flow of β phase passing through per unit cross-sectional area in unit of kg/(m²·s); q^{e} is a source and sink of energy in unit of J/(m³·s).

In an embodiment, in Step S2, the shallow gas layer and the deep-seated gas layer follow the mass conservation equation and the energy conservation equation, and the system conservation relationship is expressed as:

$$\frac{\partial {M}^{X}}{\partial t} + ∇ \cdot {F}^{X} = {q}^{X} ;$$

where x is a gas component g or energy e; M^{x} is a sum of all components of x in unit of kg/m³ or J/m³; F^{x} is the flowable component of x in unit of kg/(m²·s); q^{x} is the source and sink of x in unit of kg/(m³·s) or J/(m³·s).

When the mass of the gas component is conserved,

$$\begin{matrix}{M}^{g} = ∅ {S}_{G} {ρ}_{G} {X}_{G} ; \\ {F}^{g} = {X}_{G} {F}_{G} ; \\ {q}^{g} = {X}_{q , G} {q}_{G} ;\end{matrix}$$

where M^{g} is a sum of the mass of the gas component in unit of kg/m³; X_{G} is a ratio of the mass of the gas component to the mass of the gas phase; F^{g} is a mass flow of the gas component passing through per unit cross-sectional area in unit of kg/(m²·s); q^{g} is a source and sink of the gas component in unit of kg/(m³·s); X_{q,G} is a ratio of the mass of the gas component to the mass of the source and sink of the gas phase.

When the energy is conserved,

$$\begin{matrix}{M}^{e} = ( 1 - ϕ ) {ρ}_{R} {H}_{R} + ϕ {s}_{G} {ρ}_{G} {H}_{G} ; \\ {F}^{e} = - {K}_{c} ∇ T + {H}_{G} {F}_{G} ; \\ {q}^{e} = {H}_{G} {q}_{G} ;\end{matrix}$$

where s_{G} is a saturation of the gas phase; H_{G} is an enthalpy of the gas phase in unit of J/kg; F_{G} is the mass flow of the gas phase passing through per unit cross-sectional area in unit of kg/(m²·s).

In an embodiment, in Step S2, the temperature of the deep-seated gas layer is low, and a compressibility of an actual gas is quite different from that of an ideal gas, so a deviation factor is introduced into a gas state equation:

$$pV = nZRT ;$$

where p is a gas absolute pressure in unit of Mpa; T is a gas of absolute temperature in unit of K; V is a gas volume in unit of m³; n is an amount of gas substance in unit of mol; R is a gas constant, which is 8.314×10⁻³ Mpa/(mol·K); Z is a deviation factor of the natural gas which is dimensionless.

Gas seepage is similar to liquid seepage, when gas is in a laminar flow state, Darcy's seepage law is used to describe a flow state, and for a homogeneous formation and in three-dimensional seepage space, a generalized Darcy's law is:

$$v = - \frac{K}{μ} ∇ p .$$

A flow velocity of gas flow in the three-dimensional space is expressed as:

$$\begin{matrix}{v}_{x} = - \frac{K}{μ} \frac{\partial p}{\partial x} ; \\ {v}_{y} = - \frac{K}{μ} \frac{\partial p}{\partial y} ; \\ {v}_{z} = - \frac{K}{μ} ( \frac{\partial p}{\partial z} + ρ g ) ;\end{matrix}$$

where v is a gas seepage velocity in unit of m/s; K is a formation permeability in unit of D; μ is a gas viscosity in unit of mPa·s; g is a gravity acceleration in unit of g/cm³; x, y and z are space coordinate axes.

When the gas seepage velocity increases to a certain extent, influence of a turbulence and an inertia will become more and more obvious, there is a nonlinear relationship between a seepage velocity and a pressure gradient, which does not satisfy the Darcy's seepage law; in horizontal direction, when there is turbulence and inertia resistance in a process of gas seepage, a nonlinear quadratic equation of motion satisfying dynamic law of the natural gas is:

$$\frac{dp}{dx} = - ( \frac{μ}{K} v + ζρ {v}^{2} ) ;$$

where ξ is a characteristic parameter of a pore structure which influences the turbulence and the inertial resistance;
a first term at the right end of the above equation is viscosity resistance which is proportional to the seepage velocity, and a second term is inertia resistance which is proportional to square of the seepage velocity, thus when the seepage velocity is small, the influence of the inertia resistance is not taken into account; when the seepage velocity is large, the influence of the turbulence and the inertia is gradually obvious, and when the seepage velocity increases to deviate from the Darcy's law, the inertia will play a leading role; therefore, the above equation is a generalized equation of motion, so that Darcy's law becomes:

$$v = - δ \frac{K}{μ} \frac{dp}{dx} ;$$

$$where$$

$$δ = \frac{1}{( 1 + ζρ Kv / μ )} ;$$

where δ is a turbulence correction coefficient.

In process of joint exploitation of hydrate, shallow gas and deep-seated gas, calculation equations of a water phase relative permeability k_{rw}, a gas phase relative permeability k_{rg} and the capillary pressure P_{c} are, respectively,

$${k}_{rw} = {k}_{r w 0} {{\overline{{S}_{w}}}^{1 / m} [ 1 - {( 1 - {\overline{{S}_{w}}}^{1 / m} )}^{m} ]}^{2} ;$$

$${k}_{rg} = {k}_{rg 0} {{\overline{{S}_{g}}}^{1 / m} [ 1 - {\overline{{S}_{wh}}}^{1 / m} ]}^{m} ;$$

$${P}_{c} = {{P}_{c 0} [ \begin{matrix}{\overline{{S}_{w}}}^{1 / m} & - 1\end{matrix} ]}^{1 - m} ;$$

$$where$$

$$\overline{{S}_{w}} = ( {S}_{w} - {S}_{wr} ) / ( 1 - {S}_{wr} - {S}_{gr} ) ;$$

where S_{wr} is a bound water saturation, S_{gr} is a residual gas saturation, k_{rw0} and k_{rg0} are endpoint values of permeability, P_{c0} is an endpoint value of the capillary pressure, and m is a van Genuchten parameter.

A second aspect of the present disclosure provides a simulation system of joint exploitation of natural gas hydrate, shallow gas and deep-seated gas, including:
a simulation module of joint exploitation of natural gas hydrate and shallow gas, which is configured to set and mesh the shallow gas layer and the hydrate layer, set a geological parameter, a production parameter and a well control parameter, etc, construct a simulation model of joint exploitation, and solve the model to acquire productivity data;
a simulation module of joint exploitation of natural gas hydrate, shallow gas and deep-seated gas, which is configured to, on the basis of the simulation module of joint exploitation of natural gas hydrate and shallow gas, add a deep-seated gas layer below the hydrate layer, mesh the deep-seated gas layer, set the geological parameter and the production parameter, construct a simulation model of joint exploitation of the shallow gas layer, the deep-seated gas layer and the hydrate layer, and solve the simulation model of joint exploitation of the shallow gas layer, the deep-seated gas layer and the hydrate layer to acquire productivity data.

A third aspect of the present disclosure provides a computer device, including a processor and a memory for storing instructions executable by the processor, where the processor, when executing the instructions, implements steps of the method described above.

A fourth aspect of the present disclosure proposes a non-transitory computer-readable storage medium having computer instructions stored thereon, where the instructions, when executed, implements steps of the method described above.

The present disclosure has the following beneficial effects.

Based on an interaction mechanism of a seepage field, a temperature field and a mechanical field, the simulation method of joint exploitation of natural gas hydrate, shallow gas and deep-seated gas according to the present disclosure carries out three-field coupled flow simulation, and ascertains a productivity change rule of two-gas joint exploitation and three-gas joint exploitation. The numerical simulation models of two-gas joint exploitation and three-gas joint exploitation are constructed, the time-varying law and evolution characteristics of physical property parameters of multi-gas joint exploitation reservoirs can be effectively clarified, the changing law of physical property parameters of reservoirs in different exploitation stages can be clearly defined, thereby providing a theoretical and technical support for realizing multi-gas joint exploitation of marine gas hydrate.

### BRIEF DESCRIPTION OF THE DRAWINGS

FIG. 1 is a flow chart of a simulation method and system of joint exploitation of natural gas hydrate, shallow gas and deep-seated gas and a system thereof according to an embodiment of the present disclosure.

FIG. 2 is a schematic diagram of a simulation model of joint exploitation of a shallow gas layer and a hydrate layer constructed according to an embodiment of the present disclosure.

FIG. 3 is a graph showing the law that the cumulative gas production generated by the joint exploitation of natural gas hydrate and shallow gas and the gas production rate change with time at the bottom hole flowing pressure of 3.75 MPa according to an embodiment of the present disclosure.

FIG. 4 is a schematic diagram of a simulation model of joint exploitation of a shallow gas layer, a deep-seated gas layer and a hydrate layer constructed according to an embodiment of the present disclosure.

FIG. 5 is a graph showing the law that the cumulative gas production generated by the joint exploitation of shallow gas, deep-seated gas and natural gas hydrate and the gas production rate change with time at the bottom hole flowing pressure of 3.75 MPa according to an embodiment of the present disclosure.

### DETAILED DESCRIPTION OF THE EMBODIMENTS

The technical schemes in the embodiments of the present disclosure will be clearly and completely described with reference to the drawings in the embodiments of the present disclosure hereinafter. Obviously, the described embodiments are only some embodiments of the present disclosure, rather than all of the embodiments. Based on the embodiment of the present disclosure, all other embodiments obtained by those skilled in the art without creative labor fall within the scope of protection of the present disclosure.

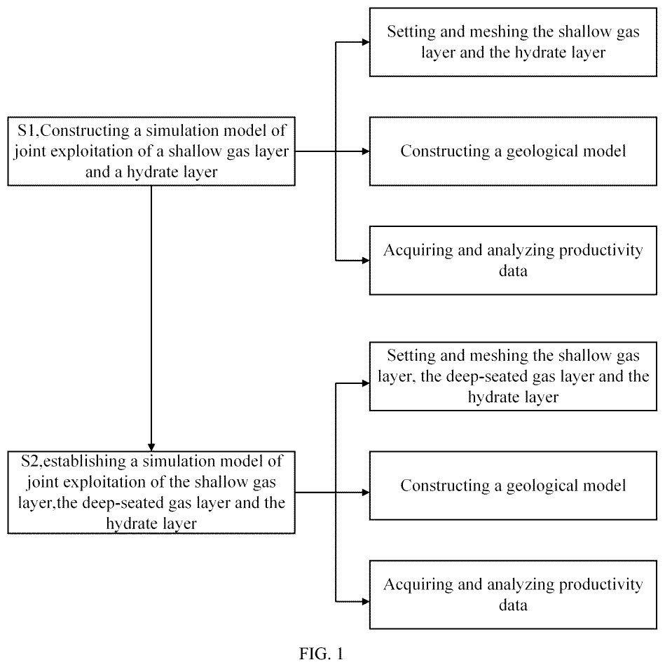

As shown in FIG. 1, the simulation method of joint exploitation of natural gas hydrate, shallow gas and deep-seated gas includes the following steps.

S1, constructing a simulation model of joint exploitation of a shallow gas layer and a hydrate layer, includes: setting and meshing the shallow gas layer and the hydrate layer setting a geological parameter, a production parameter, a well control parameter, etc.; constructing the simulation model of joint exploitation, and solving the model to acquire productivity data. A hydrate decomposition kinetic equation is:

CH₄·NₕH₂O [symbol] CH_{4(g)}+NₕH₂O₍₁₎;
where Nₕ is the number of water molecules bound by hydrate.

The hydrate layer follows a mass conservation equation and an energy conservation equation, and a system conservation relationship is expressed as:

$$\frac{\partial {M}^{κ}}{\partial t} + ∇ \cdot {F}^{κ} = {q}^{κ} ;$$

where t is time in unit of s; κ is a component identifier, and in the system conservation relationship, it represents a hydrate component h, a methane component m, a water component w or energy e; M^{κ} is the sum of all components of κ in unit of kg/m³ or J/m³; F^{κ} is a flowable component of κ in unit of kg/(m²·s); q^{κ} is the source and sink of κ in unit of kg/(m³·s) or J/(m³·s).

The mass conservation equation of the hydrate component is:

$${M}^{h} = ϕ {S}_{H} {ρ}_{H} ;$$

where M^{h} is the sum of the mass of the hydrate component in unit of kg/m³; S_{H} is the saturation of a hydrate phase; ρ_{H} is the density of the hydrate phase in unit of kg/m³.

The mass conservation equation of the methane component is:

$${M}^{m} = ϕ {S}_{A} {ρ}_{A} {X}_{A}^{m} + ϕ {S}_{G} {ρ}_{G} {X}_{G}^{m} + ϕ {S}_{H} {ρ}_{H} {X}_{H}^{m} ;$$

$${F}^{m} = {X}_{A}^{m} {F}_{A} + {X}_{G}^{m} {F}_{G} ;$$

$${q}^{m} = {X}_{q , A}^{m} {q}_{A} + {X}_{q , G}^{m} {q}_{G} ;$$

where M^{m} is the sum of the mass of the methane component in unit of kg/m³; ϕ is a porosity of a reservoir; S_{A} is the saturation of the water phase; S_{G} is the saturation of the gas phase; ρ_{A} is the density of the water phase in unit of kg/m³; ρ_{G} is the density of the gas phase in unit of kg/m³; X_{A}^{m} is the ratio of the mass of the methane component to the mass of the water phase; X_{G}^{m} is the ratio of the mass of the methane component to the mass of the gas phase; X_{H}^{m} is the ratio of the mass of the methane component to the mass of the hydrate phase; F_{A} is a mass flow of the water phase passing through per unit cross-sectional area in unit of kg/(m²·s); F_{G} is the mass flow of the gas phase passing through per unit cross-sectional area in unit of kg/(m²·s); F^{m} is the mass flow of the methane component passing through per unit cross-sectional area in unit of kg/(m²·s); q^{m} is a source and sink of the methane component in unit of kg/(m³·s); q_{A} is the source and sink of the water phase in unit of kg/(m³·s); q_{G} is the source and sink of the gas phase in unit of kg/(m³·s); X_{q,A}^{m} is the ratio of the mass of the methane component to the mass of the source and sink of the water phase; X_{q,G}^{m} is the ratio of the mass of the methane component to the mass of the source and sink of the gas phase.

The mass conservation equation of the water component is:

$${M}^{w} = ϕ {S}_{A} {ρ}_{A} {X}_{A}^{w} + ϕ {S}_{G} {ρ}_{G} {X}_{G}^{w} + ϕ {S}_{H} {ρ}_{H} {X}_{H}^{w} ;$$

$${F}^{w} = {X}_{A}^{w} {F}_{A} + {X}_{G}^{w} {F}_{G} ;$$

$${q}^{w} = {X}_{q , A}^{w} {q}_{A} + {X}_{q , G}^{w} {q}_{G} ;$$

where M^{w} is the sum of the mass of the water component in unit of kg/m³; X_{A}^{w} is the ratio of the mass of the water component to the mass of the water phase; X_{G}^{w} is the ratio of the mass of the water component to the mass of the gas phase; X_{H}^{w} is the ratio of the mass of the water component to the mass of the hydrate phase; F^{w} is the mass flow of the water component passing through per unit cross-sectional area in unit of kg/(m²·s); q^{w} is the source and sink of the water component in unit of kg/(m³·s); X_{q,A}^{w}, is the ratio of the mass of the water component to the mass of the source and sink of the water phase; X_{q,G}^{w} is the ratio of the mass of the water component to the mass in the source and sink of the gas phase.

The energy conservation equation is:

$${M}^{e} = ( 1 - ϕ ) {ρ}_{R} {H}_{R} + {\sum }_{β = A , G , H} ϕ {s}_{β} {ρ}_{β} {H}_{β} + {ϕρ}_{H} Δ {s}_{H} Δ {H}_{0} ;$$

$${F}^{e} = - {K}_{c} ∇ T + {\sum }_{β = A , G} {H}_{β} {F}_{β} ;$$

$${q}^{e} = {\sum }_{β = A , G} {H}_{β} {q}_{β} ;$$

where M^{e} is the sum of energy in unit of J/m³; ρ_{R} is the density of rock in unit of kg/m³; H_{R} is the enthalpy of rock in unit of J/kg; s_{β} is the saturation of β phase; H_{β} is the enthalpy of β phase in unit of J/kg; Δs_{H} is the change value of the hydrate saturation in the current time step; ΔH₀ is the decomposition/formation enthalpy of hydrate in unit of J/kg; F^{e} is the energy flow rate in unit of J/(m²·s); K_{c} is a comprehensive thermal conductivity of the system in unit of W/(m·K); F_{β} is the mass flow of β phase passing through per unit cross-sectional area in unit of kg/(m²·s); q^{e} is the source and sink of energy in unit of J/(m³·s).

S2, on the basis of Step S1, a deep-seated gas layer is added below the hydrate layer, the deep-seated gas layer is meshed, the geological parameter, and the production parameter, etc. are set, a simulation model of joint exploitation of the shallow gas layer, the deep-seated gas layer and the hydrate layer is constructed, and the simulation model of joint exploitation of the shallow gas layer, the deep-seated gas layer and the hydrate layer is solved to acquire productivity data.

The shallow gas layer and the deep-seated gas layer follow the mass conservation equation and the energy conservation equation, and the system conservation relationship is expressed as:

$$\frac{\partial {M}^{x}}{\partial t} + ∇ \cdot {F}^{x} = {q}^{x} ;$$

where x is the gas component g or energy e; M^{x} is the sum of all components of x in unit of kg/m³ or J/m³; F^{x} is the flowable component of x in unit of kg/(m²·s); q^{x} is the source and sink of x in unit of kg/(m³·s) or J/(m³·s).

When the mass of the gas component is conserved,

$${M}^{g} = ϕ {S}_{G} {ρ}_{G} {X}_{G} ;$$

$${F}^{g} = {X}_{G} {F}_{G} ;$$

$${q}^{g} = {X}_{q , G} {q}_{G} ;$$

where M^{g} is the sum of the mass of the gas component in unit of kg/m³; X_{G} is the ratio of the mass of the gas component to the mass of the gas phase; F^{g} is the mass flow of the gas component passing through per unit cross-sectional area in unit of kg/(m²·s); q^{g} is the source and sink of the gas component in unit of kg/(m³·s); X_{q,G} is the ratio of the mass of the gas component to the mass of the source and sink of the gas phase.

When the energy is conserved:

$${M}^{e} = ( 1 - ϕ ) {ρ}_{R} {H}_{R} + ϕ {s}_{G} {ρ}_{G} {H}_{G} ;$$

$${F}^{e} = - {K}_{c} ∇ T + {H}_{G} {F}_{G} ;$$

$${q}^{e} = {H}_{G} {q}_{G} ;$$

where s_{G} is the saturation of the gas phase; H_{G} is the enthalpy of the gas phase in unit of J/kg; F_{G} is the mass flow of the gas phase passing through per unit cross-sectional area in unit of kg/(m²·s).

The temperature of the deep-seated gas layer is low, and a compressibility of an actual gas is quite different from that of an ideal gas, so a deviation factor is introduced into a gas state equation:

$$pV = nZRT ;$$

where p is a gas absolute pressure in unit of Mpa; T is a gas absolute temperature in unit of K; V is a gas volume in unit of m³; n is an amount of gas substance in unit of mol; R is a gas constant, which is 8.314×10⁻³ Mpa/(mol·K); Z is a deviation factor of gas which is dimensionless.

Gas seepage is similar to liquid seepage, when gas is in a laminar state, Darcy's seepage law is used to describe the flow state, and for a homogeneous formation and in the three-dimensional seepage space, a generalized Darcy's law is:

$$v = - \frac{K}{μ} ∇ p .$$

The flow velocity of gas flow in the three-dimensional space is expressed as:

$${v}_{x} = - \frac{K}{μ} \frac{\partial p}{\partial x} ;$$

$${v}_{y} = - \frac{K}{μ} \frac{\partial p}{\partial y} ;$$

$${v}_{z} = - \frac{K}{μ} ( \frac{\partial p}{\partial z} + ρ g ) ;$$

where v is a gas seepage velocity in unit of m/s; K is a formation permeability in unit of D; μ is the gas viscosity in unit of mPa·s; g is the gravity acceleration in unit of g/cm³; x, y and z are space coordinate axes.

When the gas seepage velocity increases to a certain extent, influence of a turbulence and an inertia will become more and more obvious, there is a nonlinear relationship between a seepage velocity and a pressure gradient, which does not satisfy the Darcy's seepage law; in horizontal direction, when there is turbulence and inertia resistance in the process of gas seepage, a nonlinear quadratic equation of motion satisfying dynamic law of the natural gas is:

$$\frac{dp}{dx} = - ( \frac{μ}{K} v + ζρ {v}^{2} ) ;$$

where ξ is a characteristic parameter of a pore structure which influences the turbulence and the inertial resistance;
a first term at the right end of the above equation is viscosity resistance which is proportional to the seepage velocity, and a second term is inertia resistance which is proportional to the square of the seepage velocity, thus when the seepage velocity is small, the influence of the inertia resistance is not taken into account; when the seepage velocity is large, the influence of the turbulence and the inertia is gradually obvious, and when the seepage velocity increases to deviate from the Darcy's law, the inertia will play a leading role; therefore, the above equation is a generalized equation of motion, so that Darcy's law becomes:

$$v = - δ \frac{K}{μ} \frac{dp}{dx} ;$$

$$where$$

$$δ = \frac{1}{( 1 + ζρ Kv / μ )} ;$$

where δ is a turbulence correction coefficient.

In the process of joint exploitation of hydrate, shallow gas and deep-seated gas, the calculation equation of a water phase relative permeability k_{rw}, a gas phase relative permeability k_{rg} and the capillary pressure P_{c} are, respectively,

$${k}_{rw} = {k}_{rw 0} {{\overline{{S}_{w}}}^{1 / 2} [ 1 - {( 1 - {\overline{{S}_{w}}}^{1 / m} )}^{m} ]}^{2} ;$$

$${k}_{rg} = {k}_{rg 0} {{\overline{{S}_{g}}}^{1 / 2} [ 1 - {\overline{{S}_{wh}}}^{1 / m} ]}^{m} ;$$

$${P}_{c} = {{P}_{c 0} [ {\overline{{S}_{w}}}^{1 / m} - 1 ]}^{1 - m} ;$$

$$where$$

$$\overline{{S}_{w}} = ( {S}_{w} - {S}_{wr} ) / ( 1 - {S}_{wr} - {S}_{gr} ) ;$$

$$\overline{{S}_{wh}} = ( {S}_{w} + {S}_{h} - {S}_{wr} ) / ( 1 - {S}_{wr} - {S}_{gr} ) ;$$

where S_{wr} is a bound water saturation, S_{gr} is a residual gas saturation, k_{rw0} and k_{rg0} are endpoint values of permeability, P_{c0} is an endpoint value of the capillary pressure, and m is a van Genuchten parameter.

The embodiment of the present disclosure further provides a simulation system of joint exploitation of natural gas hydrate, shallow gas and deep-seated gas, including a simulation module of joint exploitation of natural gas hydrate and shallow gas and a simulation module of joint exploitation of natural gas hydrate, shallow gas and deep-seated gas.

The simulation module of joint exploitation of natural gas hydrate and shallow gas, which is configured to set and mesh the shallow gas layer and the hydrate layer, set a geological parameter, a production parameter and a well control parameter, construct the simulation model of joint exploitation, and solve the model to acquire productivity data.

The simulation module of joint exploitation of natural gas hydrate, shallow gas and deep-seated gas, which is configured to, on the basis of the simulation module of joint exploitation of natural gas hydrate and shallow gas, add a deep-seated gas layer below the hydrate layer, mesh the deep-seated gas layer, set the geological parameter and the production parameter, construct a simulation model of joint exploitation of the shallow gas layer, the deep-seated gas layer and the hydrate layer, and solve the simulation model of joint exploitation of the shallow gas layer, the deep-seated gas layer and the hydrate layer to acquire productivity data.

The embodiment of the present disclosure further provides a computer device, including a processor and a memory for storing instructions executable by the processor, where the processor, when executing the instructions, implements steps of the method described above.

The embodiment of the present disclosure further provides a non-transitory computer-readable storage medium having computer instructions stored thereon, where the instructions, when executed, implements steps of the method described above. Those skilled in the art can understand that all or part of the processes in the method of implementing the above embodiments can be completed by instructing related hardware through a computer program. The computer program can be stored in a non-transitory computer-readable storage medium. When executed, the computer program can include the processes of the embodiments of each method described above. Any reference to the memory, the storage, the database or other media used in various embodiments provided by the present disclosure may include at least one of a non-volatile memory and a volatile memory. The non-volatile memory may include a Read-Only Memory (ROM), a magnetic tape, a floppy disk, a flash memory or an optical memory, etc. The volatile memory may include a Random Access Memory (RAM) or an external cache. By way of illustration and not limitation, RAM can be in various forms, such as a Static Random Access Memory (SRAM) or a Dynamic Random Access Memory (DRAM).

The technical scheme of the present disclosure will be further described with reference to the embodiments.

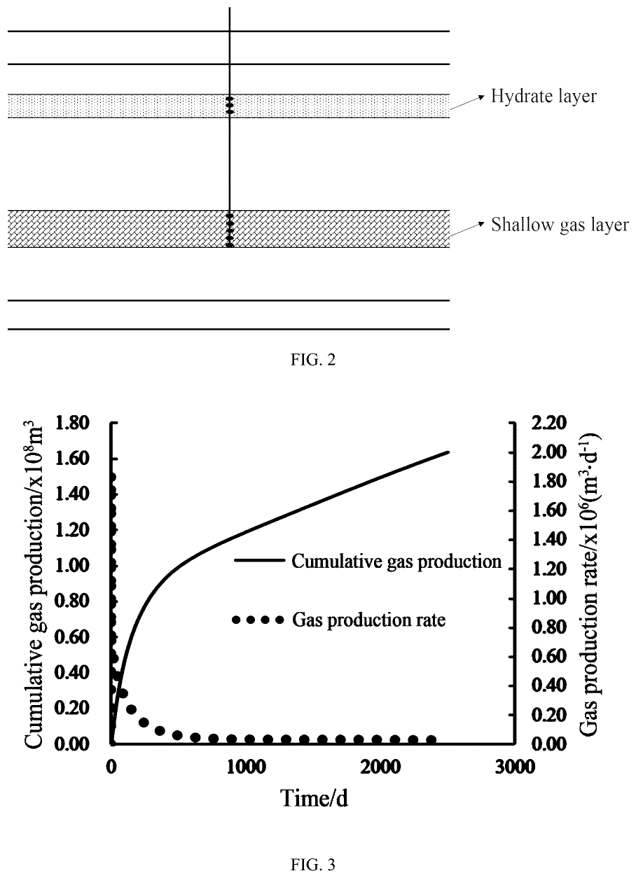

As shown in FIG. 2, the embodiment of the present disclosure only takes into account a shallow gas layer and a natural gas hydrate layer. The upper capping formation and the lower capping formation of the model are impermeable. The data refer to the logging data from China Geological Survey on the pilot production of natural gas hydrate in Shenhu waters of South China Sea in 2017. The depth of the seabed level from the sea level is 1200 m, the pressure at the seabed is 11760 kPa, and the seabed temperature is 3.8° C. The density of seabed sediments is 2600 kg/m³, and the specific heat capacity of sediments is 1000 J/(kg·° C.). At the same time, the depth of the natural gas hydrate layer from the sea surface is set to 1530 m, and the depth of shallow gas layer from the sea surface is set to 1700 m.

The model is 560 m×560 m×285 m in size, 560 m in length and width, and 285 m in thickness. The model is divided into 56 grids in XY direction and 35 grids in the vertical direction. The model consists of four layers, namely, an upper capping formation and a lower capping formation, a hydrate layer and a shallow gas layer. The upper capping formation and the lower capping formation are 40 m thick and divided into four grids. The hydrate layer with a thickness of 15 m, is divided into five grids. The shallow gas layer with a thickness of 35 m, is divided into five grids. Other geological types with a thickness of 170 m between the gas hydrate layer and the shallow gas layer are set as invalid grids, and the influence of formation parameters on the results is ignored. A vertical well in the center of the model is depressurized and drilled from the top of the shallow gas layer to the bottom of the hydrate layer. The geological model divided by the formation thickness is shown in FIG. 2, in which the area between the hydrate layer and the shallow gas layer is an invalid grid area.

The hydrate layer with a thickness of 15 m, includes water, natural gas hydrate and methane gas, with an effective porosity of 33%, a hydrate saturation of 31% and a permeability of 1.5 mD. The shallow gas layer has a thickness of 35 m, a porosity of 25% and a permeability of 6 mD. The reservoir contains a methane phase and a gas phase.

FIG. 3 is a graph showing the law that the cumulative gas production generated by the joint exploitation of natural gas hydrate, shallow gas and deep-seated gas and the gas production rate change with time at the bottom hole flowing pressure of 3.75 MPa. From FIG. 3, it can be seen that the gas production rate is a curve of first rising, then rapidly decreasing, and then gently decreasing, while the cumulative gas production is a curve of first rapidly increasing and then gently increasing. Therefore, the production process can be divided into two stages. (1) At a stage of mass production of free gas, a very high gas production rate is obtained in the initial period of production and then the gas production rate decreases rapidly, and the maximum gas production rate reaches 1.83×10⁶ m³/d. At this stage, there is a large amount of free gas in the shallow gas layer, so the gas production rate and the gas production at the initial period suddenly increase. After that, due to the mass production of free gas in the reservoir, the reservoir pressure decreases and the hydrate starts to decompose. The produced gas includes two parts: free gas and gas produced by hydrate decomposition. The produced gas at this stage is mainly free gas, which can achieve a great gas production rate at the initial stage of exploitation. However, the gas production rate drops rapidly due to the large decrease of free gas in the subsequent period, and the cumulative gas production starts to gradually become flat. (2) At a hydrate decomposition and gas production stage, the hydrate starts to decompose to produce decomposed gas, and the gas production rate is mainly influenced by the decomposition rate of the natural gas hydrate in the reservoir. Due to the large amount of exploitation of shallow gas, the gas pressure drops rapidly, thereby leading to the rapid increase of difference between the bottom hole pressure and the formation pressure, which promotes the decomposition of hydrate and accelerates the decomposition rate of hydrate. However, due to the endothermic decomposition of hydrate, the temperature of the hydrate layer decreases. Without the supplement of external heat, the decomposition rate of the hydrate gradually decreases, and the gas production rate has been declining. However, the decline rate is slow, which basically keeps a stable value of about 3.03×10+m³/d, thus it has good commercial exploitation value.

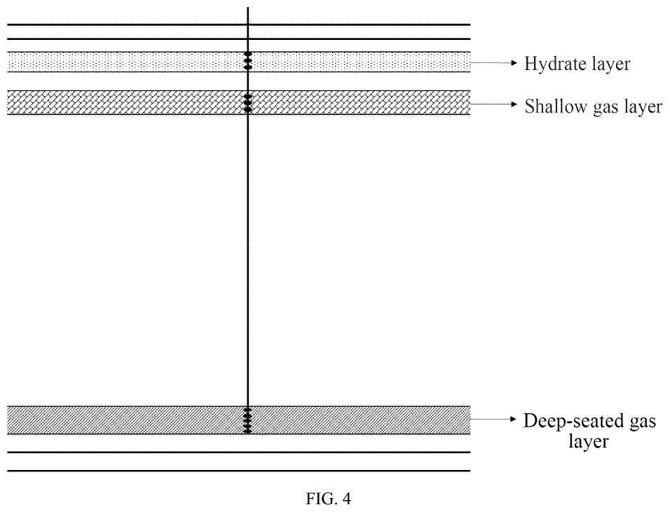

As shown in FIG. 4, the embodiment of the present disclosure takes into account the shallow gas layer, the natural gas hydrate layer and the deep-seated gas layer. The upper capping formation and the lower capping formation of the model are water-saturated layers. The depth of the natural gas hydrate layer from the sea surface is set as 1530 m, the depth of the shallow gas layer from the sea surface is set as 1700 m, and the depth of the deep-seated gas layer from the sea surface is set as 4500 m.

The model is 560 m×560 m×3077 m in size, 560 m in length and width, and 3077 m in thickness. The model is divided into 56 grids in XY direction and 131 grids in the vertical direction. The model consists of five layers, namely, an upper capping formation and a lower capping formation, a shallow gas layer, a hydrate layer and a deep-seated gas layer. The upper capping formation and the lower capping formation are 40 m thick and divided into four grids. The hydrate layer with a thickness 15 m is divided into five grids. The shallow gas layer with a thickness of 35 m is divided into five grids. The deep-seated gas layer with a thickness 27 m is divided into three grids. Other geological types with a thickness of 155 m between the shallow gas layer and the natural gas hydrate layer and other geological types with a thickness of 2765 m between the natural gas hydrate layer and the deep-seated gas layer are set as invalid grids, and the influence of formation parameters on the results is ignored. A vertical well in the center of the model is depressurized and drilled from the top of the shallow gas layer to the bottom of the deep-seated gas layer. The geological model divided by the formation thickness is shown in FIG. 4, in which the area between the hydrate layer and the shallow gas layer and the area between the shallow gas layer and the deep-seated gas layer are invalid grid areas.

The hydrate layer with a thickness of 15 m, includes water and natural gas hydrate and methane gas, in which the effective porosity is 33%, the hydrate saturation is 31%, and the permeability is 1.5 mD. The thickness of the shallow gas layer is 35 m, the porosity is 25%, the permeability is 6 mD. The reservoir contains methane gas. The deep-seated gas layer with a thickness of 27 m, includes methane gas, in which the effective porosity is 32%, and the permeability is 7.4 mD.

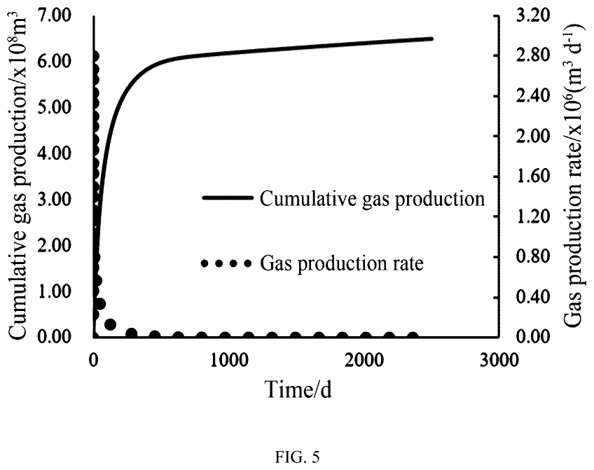

FIG. 5 is a graph showing the law that the cumulative gas production generated by the multi-gas joint exploitation model and the gas production rate change with time at the bottom hole flowing pressure of 3.75 MPa. From FIG. 5, it can be seen that the gas production rate is a curve of first rising, then rapidly decreasing, and then gently decreasing, while the cumulative gas production is a curve of first rapidly increasing and then gently increasing. Therefore, the production process can be divided into two stages. (1) At a stage of mass production of free gas, a very high gas production rate is obtained in the initial period of production and then the gas production rate decreases rapidly, and the maximum gas production rate reaches 2.82×10⁷ m³/d. At this stage, there is a large amount of free gas in the shallow gas layer and the deep-seated gas layer, so the gas production rate and the gas production at the initial period suddenly increase. The produced gas mainly comes from free gas in the reservoir and methane gas converted from hydrate. The produced gas at this stage is mainly free gas, which can achieve a great gas production rate at the early stage of exploitation. However, the gas production rate drops rapidly due to the large decrease of free gas in the subsequent period, and the cumulative gas production starts to gradually become flat. (2) At a hydrate decomposition and gas production stage, the hydrate starts to decompose to produce methane gas, and the gas production rate is mainly influenced by the decomposition rate of the natural gas hydrate in the reservoir. Due to the large amount of exploitation of shallow gas and deep-seated gas, the gas pressure drops rapidly, thereby leading to the rapid increase of the difference between the bottom hole pressure and the formation pressure, which promotes the decomposition of hydrate and accelerates the decomposition rate of hydrate. Therefore, in order to study the influence of hydrate decomposition on gas well productivity, it is necessary to accurately measure the law of gas production changing with time under different conditions. However, due to the endothermic decomposition of hydrate, the temperature of the hydrate layer decreases. Without the supplement of external heat, the decomposition rate of the hydrate gradually decreases, and the gas production rate has been declining. However, the decline rate is slow, which basically keeps a stable value of about 1.81×10⁴ m³/d.

Of course, the above description is not a limitation of the present disclosure, and the present disclosure is not limited to the above examples. Changes, modifications, additions or substitutions made by those skilled in the art within the essential scope of the present disclosure should also belong to the scope of protection of the present disclosure.

What is claimed is:

1. A simulation method of joint exploitation of natural gas hydrate, shallow gas and deep-seated gas, comprising:
Step S1, constructing a simulation model of joint exploitation of a shallow gas layer and a hydrate layer, comprising setting and meshing the shallow gas layer and the hydrate layer, setting a geological parameter, a production parameter and a well control parameter, constructing the simulation model of joint exploitation, and solving the model to acquire productivity data;
Step S2, on basis of Step S1, adding a deep-seated gas layer below the hydrate layer, meshing the deep-seated gas layer, setting the geological parameter and the production parameter, constructing a simulation model of joint exploitation of the shallow gas layer, the deep-seated gas layer and the hydrate layer, and solving the simulation model of joint exploitation of the shallow gas layer, the deep-seated gas layer and the hydrate layer to acquire productivity data;
wherein in Step S1, a hydrate decomposition kinetic equation is:
CH₄·NₕH₂O [symbol] CH_{4(g)}+NₕH₂O₍₁₎;
wherein Nₕ is a number of water molecules bound by hydrate;
the hydrate layer follows a mass conservation equation and an energy conservation equation, and a system conservation relationship is expressed as:
$$\frac{\partial {M}^{κ}}{\partial t} + ∇ \cdot {F}^{κ} = {q}^{κ} ;$$
where t is time in unit of s; κ is a component identifier, and in the system conservation relationship, κ represents a hydrate component h, a methane component m, a water component w or energy e; M^{κ} is a sum of all components of κ in unit of kg/m³ or J/m³; F^{κ} is a flowable component of κ in unit of kg/(m²·s); q^{κ} is a source and sink of κ in unit of kg/(m³·s) or J/(m³·s);
the mass conservation equation of the hydrate component is:
$${M}^{h} = ϕ {S}_{H} {ρ}_{H} ;$$
where M^{h} is a sum of a mass of the hydrate component in unit of kg/m³; S_{H} is a saturation of a hydrate phase; ρ_{H} is a density of the hydrate phase in unit of kg/m³;
the mass conservation equation of the methane component is:
$${M}^{m} = ϕ {S}_{A} {ρ}_{A} {X}_{A}^{m} + ϕ {S}_{G} {ρ}_{G} {X}_{G}^{m} + ϕ {S}_{H} {ρ}_{H} {X}_{H}^{m} ;$$
$${F}^{m} = {X}_{A}^{m} {F}_{A} + {X}_{G}^{m} {F}_{G} ;$$
$${q}^{m} = {X}_{q , A}^{m} {q}_{A} + {X}_{q , G}^{m} {q}_{G} ;$$
where M^{m} is a sum of a mass of the methane component in unit of kg/m³; ϕ is a porosity of a reservoir; S_{A} is a saturation of a water phase; S_{G} is a saturation of a gas phase; ρ_{A} is a density of the water phase in unit of kg/m³; ρ_{G} is a density of the gas phase in unit of kg/m³; X_{A}^{m} is a ratio of the mass of the methane component to a mass of the water phase; X_{G}^{m} is a ratio of the mass of the methane component to a mass of the gas phase; X_{H}^{m} is a ratio of the mass of the methane component to a mass of the hydrate phase; F_{A} is a mass flow of the water phase passing through per unit cross-sectional area in unit of kg/(m²·s); F_{G} is a mass flow of the gas phase passing through per unit cross-sectional area in unit of kg/(m²·s); F^{m} is a mass flow of the methane component passing through per unit cross-sectional area in unit of kg/(m²·s); q^{m} is a source and sink of the methane component in unit of kg/(m³·s); q_{A} is a source and sink of the water phase in unit of kg/(m³·s); q_{G} is a source and sink of the gas phase in unit of kg/(m³·s); X_{q,A}^{m} is a ratio of the mass of the methane component to a mass of the source and sink of the water phase; X_{q,G}^{m} is a ratio of the mass of the methane component to a mass of the source and sink of the gas phase;
the mass conservation equation of the water component is:
$${M}^{w} = ϕ {S}_{A} {ρ}_{A} {X}_{A}^{w} + ϕ {S}_{G} {ρ}_{G} {X}_{G}^{w} + ϕ {S}_{H} {ρ}_{H} {X}_{H}^{w} ;$$
$${F}^{w} = {X}_{A}^{w} {F}_{A} + {X}_{G}^{w} {F}_{G} ;$$
$${q}^{w} = {X}_{q , A}^{w} {q}_{A} + {X}_{q , G}^{w} {q}_{G} ;$$
where M^{w} is a sum of a mass of the water component in unit of kg/m³; X_{A}^{w} is a ratio of the mass of the water component to the mass of the water phase; X_{G}^{w} is a ratio of the mass of the water component to the mass of the gas phase; X_{H}^{w} is a ratio of the mass of the water component to the mass of the hydrate phase; F^{w} is a mass flow of the water component passing through per unit cross-sectional area in unit of kg/(m²·s); q^{w} is a source and sink of the water component in unit of kg/(m³·s); X_{q,A}^{w} is a ratio of the mass of the water component to the mass of the source and sink of the water phase; X_{q,G}^{w} is a ratio of the mass of the water component to a mass in the source and sink of the gas phase;
the energy conservation equation is:
$${M}^{e} = ( 1 - ϕ ) {ρ}_{R} {H}_{R} + {\sum }_{β = A , G , H} ϕ {s}_{β} {ρ}_{β} {H}_{β} + ϕ {ρ}_{H} Δ {s}_{H} Δ {H}_{0} ;$$
$${F}^{e} = - {K}_{c} ∇ T + {\sum }_{β = A , G} {H}_{β} {F}_{β} ;$$
$${q}^{e} = {\sum }_{β = A , G} {H}_{β} {q}_{β} ;$$
where M^{e} is a sum of energy in unit of J/m³; ρ_{R} is a density of rock in unit of kg/m³; H_{R} is an enthalpy of rock in unit of J/kg; s_{β} is a saturation of β phase; H_{β} is an enthalpy of β phase in unit of J/kg; Δs_{H} is a change value of a hydrate saturation in current time step; ΔH₀ is decomposition/formation enthalpy of hydrate in unit of J/kg; F^{e} is energy flow rate in unit of J/(m²·s); K_{c} is a comprehensive thermal conductivity of a system in unit of W/(m·K); F_{β} is a mass flow of β phase passing through per unit cross-sectional area in unit of kg/(m²·s); q^{e} is a source and sink of energy in unit of J/(m³·s).

2. The simulation method according to claim 1, wherein in Step S2, the shallow gas layer and the deep-seated gas layer follow the mass conservation equation and the energy conservation equation, and the system conservation relationship is expressed as:
$$\frac{\partial {M}^{x}}{\partial t} + ∇ \cdot {F}^{x} = {q}^{x} ;$$
where x is a gas component g or energy e; M^{x} is a sum of all components of x in unit of kg/m³ or J/m³; F^{x} is a flowable component of x in unit of kg/(m²·s); q^{x} is a source and sink of x in unit of kg/(m³·s) or J/(m³·s);
when a mass of the gas component is conserved,
$${M}^{g} = ϕ {S}_{G} {ρ}_{G} {X}_{G} ;$$
$${F}^{g} = {X}_{G} {F}_{G} ;$$
$${q}^{g} = {X}_{q , G} {q}_{G} ;$$
where M^{g} is a sum of the mass of the gas component in unit of kg/m³; X_{G} is a ratio of the mass of the gas component to the mass of the gas phase; F^{g} is a mass flow of the gas component passing through per unit cross-sectional area in unit of kg/(m²·s); q^{g} is a source and sink of the gas component in unit of kg/(m³·s); X_{q,G} is a ratio of the mass of the gas component to the mass of the source and sink of the gas phase;
when the energy is conserved,
$${M}^{e} = ( 1 - ϕ ) {ρ}_{R} {H}_{R} + ϕ {s}_{G} {ρ}_{G} {H}_{G} ;$$
$${F}^{e} = - {K}_{c} ∇ T + {H}_{G} {F}_{G} ;$$
$${q}^{e} = {H}_{G} {q}_{G} ;$$
where s_{G} is a saturation of the gas phase; H_{G} is an enthalpy of the gas phase in unit of J/kg; F_{G} is the mass flow of the gas phase passing through per unit cross-sectional area in unit of kg/(m²·s).

3. The simulation method according to claim 1, wherein in Steps S1 and S2, a gas seepage law is as follows:
introducing a deviation factor into a gas state equation:
$$pV = nZRT ;$$
where p is a gas absolute pressure in unit of Mpa; T is a gas absolute temperature in unit of K; V is a gas volume in unit of m³; n is an amount of gas substance in unit of mol; R is a gas constant, which is 8.314×10⁻³ Mpa/(mol·K); Z is a deviation factor of a natural gas which is dimensionless;
gas seepage is similar to liquid seepage, when gas is in a laminar flow state, Darcy's seepage law is used to describe a flow state, and for a homogeneous formation and in three-dimensional seepage space, a generalized Darcy's law is:
$$v = - \frac{K}{μ} ∇ p ;$$
a flow velocity of a gas flow in the three-dimensional space is expressed as:
$${v}_{x} = - \frac{K}{μ} \frac{\partial p}{\partial x} ;$$
$${v}_{y} = - \frac{K}{μ} \frac{\partial p}{\partial x} ;$$
$${v}_{z} = - \frac{K}{μ} ( \frac{\partial p}{\partial z} + ρ g ) ;$$
where v is a gas seepage velocity in unit of m/s; K is a formation permeability in unit of D; μ is a gas viscosity in unit of mPa·s; g is a gravity acceleration in unit of g/cm³; x, y and z are space coordinate axes;
when the gas seepage velocity increases beyond a predetermined value, there is a nonlinear relationship between a seepage velocity and a pressure gradient, which does not satisfy the Darcy's seepage law; in horizontal direction, when there is turbulence and inertia resistance in a process of gas seepage, a nonlinear quadratic equation of motion satisfying dynamic law of the natural gas is:
$$\frac{dp}{dx} = - {( \frac{μ}{K} v + ζ ρ {v}^{2} )}_{} ;$$
where ξ is a characteristic parameter of a pore structure which influences the turbulence and the inertial resistance;
when the seepage velocity increases to deviate from the Darcy's law, the Darcy's law becomes:
$$v = - δ \frac{K}{μ} \frac{dp}{dx} ;$$
$$wherein$$
$$δ = \frac{1}{( 1 + ζ ρ Kv / μ )} ;$$
wherein δ is a turbulence correction coefficient;
in process of joint exploitation of hydrate, shallow gas and deep-seated gas, calculation equations of a water phase relative permeability k_{rw}, a gas phase relative permeability k_{rg} and a capillary pressure P_{c} are respectively:
$${k}_{rw} = {k}_{rw 0} \overline{{S}_{w}} {}^{1 / 2} {[ 1 - {( 1 - \overline{{S}_{w}} {}^{1 / m} )}^{m} ]}^{2} ;$$
$${k}_{rg} = {k}_{rg 0} \overline{{S}_{g}} {}^{1 / 2} {[ 1 - \overline{{S}_{wh}} {}^{1 / m} ]}^{m} ;$$
$${P}_{c} = {{P}_{c 0} [ \overline{{S}_{w}} {}^{1 / m} - 1 ]}^{1 - m} ;$$
$$where$$
$$\overline{{S}_{w}} = ( {S}_{w} - {S}_{wr} ) / ( 1 - {S}_{wr} - {S}_{gr} ) ;$$
$$\overline{{S}_{wh}} = ( {S}_{w} + {S}_{h} - {S}_{wr} ) / ( 1 - {S}_{wr} - {S}_{gr} ) ;$$
where S_{wr} is a bound water saturation, S_{gr} is a residual gas saturation, k_{rw0} and k_{rg0} are endpoint values of permeability, P_{c0} is an endpoint value of the capillary pressure, and m is a van Genuchten parameter.

4. A simulation system of joint exploitation of natural gas hydrate, shallow gas and deep-seated gas, comprising:
a simulation module of joint exploitation of natural gas hydrate and shallow gas, which is configured to set and mesh the shallow gas layer and the hydrate layer, set a geological parameter, a production parameter and a well control parameter, construct a simulation model of joint exploitation, and solve the model to acquire productivity data;
a simulation module of joint exploitation of natural gas hydrate, shallow gas and deep-seated gas, which is configured to, on basis of the simulation module of joint exploitation of natural gas hydrate and shallow gas, add a deep-seated gas layer below the hydrate layer, mesh the deep-seated gas layer, set the geological parameter and the production parameter, construct a simulation model of joint exploitation of the shallow gas layer, the deep-seated gas layer and the hydrate layer, and solve the simulation model of joint exploitation of the shallow gas layer, the deep-seated gas layer and the hydrate layer to acquire productivity data.

5. A computer device, comprising a processor and a memory for storing instructions executable by the processor, wherein the processor, when executing the instructions, implements steps of the method according to claim 1.

6. The computer device according to claim 5, wherein in Step S2, the shallow gas layer and the deep-seated gas layer follow the mass conservation equation and the energy conservation equation, and the system conservation relationship is expressed as:
$$\frac{\partial {M}^{x}}{\partial t} + ∇ \cdot {F}^{x} = {q}^{x} ;$$
where x is a gas component g or energy e; M^{x} is a sum of all components of x in unit of kg/m³ or J/m³; F^{x} is a flowable component of x in unit of kg/(m²·s); q^{x} is a source and sink of x in unit of kg/(m³·s) or J/(m³·s);
when a mass of the gas component is conserved,
$${M}^{g} = ϕ {S}_{G} {ρ}_{G} {X}_{G} ;$$
$${F}^{g} = {X}_{G} {F}_{G} ;$$
$${q}^{g} = {X}_{q , G} {q}_{G} ;$$
where M^{g} is a sum of the mass of the gas component in unit of kg/m³; X_{G} is a ratio of the mass of the gas component to the mass of the gas phase; F^{g} is a mass flow of the gas component passing through per unit cross-sectional area in unit of kg/(m²·s); q^{g} is a source and sink of the gas component in unit of kg/(m³·s); X_{q,G} is a ratio of the mass of the gas component to the mass of the source and sink of the gas phase;
when the energy is conserved,
$${M}^{e} = ( 1 - ϕ ) {ρ}_{R} {H}_{R} + ϕ {s}_{G} {ρ}_{G} {H}_{G} ;$$
$${F}^{e} = - {K}_{c} ∇ T + {H}_{G} {F}_{G} ;$$
$${q}^{e} = {X}_{G} {F}_{G} ;$$
where s_{G} is a saturation of the gas phase; H_{G} is an enthalpy of the gas phase in unit of J/kg; F_{G} is the mass flow of the gas phase passing through per unit cross-sectional area in unit of kg/(m²·s).

7. The computer device according to claim 5, wherein in Steps S1 and S2, a gas seepage law is as follows:
introducing a deviation factor into a gas state equation:
$$pV = nZRT ;$$
where p is a gas absolute pressure in unit of Mpa; T is a gas absolute temperature in unit of K; V is a gas volume in unit of m³; n is an amount of gas substance in unit of mol; R is a gas constant, which is 8.314×10⁻³ Mpa/(mol·K); Z is a deviation factor of a natural gas which is dimensionless;
gas seepage is similar to liquid seepage, when gas is in a laminar flow state, Darcy's seepage law is used to describe a flow state, and for a homogeneous formation and in three-dimensional seepage space, a generalized Darcy's law is:
$$v = - \frac{K}{μ} ∇ p ;$$
a flow velocity of a gas flow in the three-dimensional space is expressed as:
$${v}_{x} = - \frac{K}{μ} \frac{\partial p}{\partial x} ;$$
$${v}_{y} = - \frac{K}{μ} \frac{\partial p}{\partial y} ;$$
$${v}_{z} = - \frac{K}{μ} ( \frac{\partial p}{\partial z} + ρ g ) ;$$
where v is a gas seepage velocity in unit of m/s; K is a formation permeability in unit of D; μ is a gas viscosity in unit of mPa s; g is a gravity acceleration in unit of g/cm³; x, y and z are space coordinate axes;
when the gas seepage velocity increases beyond a predetermined value, there is a nonlinear relationship between a seepage velocity and a pressure gradient, which does not satisfy the Darcy's seepage law; in horizontal direction, when there is turbulence and inertia resistance in a process of gas seepage, a nonlinear quadratic equation of motion satisfying dynamic law of the natural gas is:
$$\frac{dp}{dx} = - ( \frac{μ}{K} v + ζρ {v}^{2} ) ;$$
where ξ is a characteristic parameter of a pore structure which influences the turbulence and the inertial resistance;
when the seepage velocity increases to deviate from the Darcy's law, the Darcy's law becomes:
$$v = - δ \frac{K}{μ} \frac{dp}{dx} ;$$
$$wherein$$
$$δ = \frac{1}{( 1 + ζρ Kv / μ )} ;$$
wherein δ is a turbulence correction coefficient;
in process of joint exploitation of hydrate, shallow gas and deep-seated gas, calculation equations of a water phase relative permeability k_{rw}, a gas phase relative permeability k_{rg} and a capillary pressure P_{c} are respectively:
$${k}_{rw} = {k}_{rw 0} {{\overline{{S}_{w}}}^{1 / 2} [ 1 - {( 1 - {\overline{{S}_{w}}}^{1 / m} )}^{m} ]}^{2} ;$$
$${k}_{rg} = {k}_{rg 0} {{\overline{{S}_{g}}}^{1 / 2} [ 1 - {\overline{{S}_{wh}}}^{1 / m} ]}^{m} ;$$
$${P}_{c} = {{P}_{c 0} [ {\overline{{S}_{w}}}^{1 / m} - 1 ]}^{1 - m} ;$$
$$where$$
$$\overline{{S}_{w}} = ( {S}_{w} - {S}_{wr} ) / ( 1 - {S}_{wr} - {S}_{gr} ) ;$$
$$\overline{{S}_{wh}} = ( {S}_{w} + {S}_{h} - {S}_{wr} ) / ( 1 - {S}_{wr} - {S}_{gr} ) ;$$
where S_{wr} is a bound water saturation, S_{gr} is a residual gas saturation, k_{rw0} and k_{rg0} are endpoint values of permeability, P_{c0} is an endpoint value of the capillary pressure, and m is a van Genuchten parameter.

8. A non-transitory computer-readable storage medium, having computer instructions stored thereon, wherein the instructions, when executed, implements steps of the method according to claim 1.

9. The non-transitory computer-readable storage medium according to claim 8, wherein in Step S2, the shallow gas layer and the deep-seated gas layer follow the mass conservation equation and the energy conservation equation, and the system conservation relationship is expressed as:
$$\frac{\partial {M}^{x}}{\partial t} + ∇ \cdot {F}^{x} = {q}^{x} ;$$
where x is a gas component g or energy e; M^{x} is a sum of all components of x in unit of kg/m³ or J/m³; F^{x} is a flowable component of x in unit of kg/(m²·s); q^{x} is a source and sink of x in unit of kg/(m³·s) or J/(m³·s);
when a mass of the gas component is conserved,
$${M}^{g} = ϕ {S}_{G} {ρ}_{G} {X}_{G} ;$$
$${F}^{g} = {X}_{G} {F}_{G} ;$$
$${q}^{g} = {X}_{q , G} {q}_{G} ;$$
where M^{g} is a sum of the mass of the gas component in unit of kg/m³; X_{G} is a ratio of the mass of the gas component to the mass of the gas phase; F^{g} is a mass flow of the gas component passing through per unit cross-sectional area in unit of kg/(m²·s); q^{g} is a source and sink of the gas component in unit of kg/(m³·s); X_{q,G} is a ratio of the mass of the gas component to the mass of the source and sink of the gas phase;
when the energy is conserved,
$${M}^{e} = ( 1 - ϕ ) {ρ}_{R} {H}_{R} + ϕ {s}_{G} {ρ}_{G} {H}_{G} ;$$
$${F}^{e} = - {K}_{c} ∇ T + {H}_{G} {F}_{G} ;$$
$${q}^{e} = {H}_{G} {q}_{G} ;$$
where s_{G} is a saturation of the gas phase; H_{G} is an enthalpy of the gas phase in unit of J/kg; F_{G} is the mass flow of the gas phase passing through per unit cross-sectional area in unit of kg/(m²·s).

10. The non-transitory computer-readable storage medium according to claim 8, wherein in Steps S1 and S2, a gas seepage law is as follows:
introducing a deviation factor into a gas state equation:
$$pV = nZRT ;$$
where p is a gas absolute pressure in unit of Mpa; T is a gas absolute temperature in unit of K; V is a gas volume in unit of m³; n is an amount of gas substance in unit of mol; R is a gas constant, which is 8.314×10⁻³ Mpa/(mol·K); Z is a deviation factor of a natural gas which is dimensionless;
gas seepage is similar to liquid seepage, when gas is in a laminar flow state, Darcy's seepage law is used to describe a flow state, and for a homogeneous formation and in three-dimensional seepage space, a generalized Darcy's law is:
$$v = - \frac{K}{μ} ∇ p ;$$
a flow velocity of a gas flow in the three-dimensional space is expressed as:
$${v}_{x} = - \frac{K}{μ} \frac{\partial p}{\partial x} ;$$
$${v}_{y} = - \frac{K}{μ} \frac{\partial p}{\partial y} ;$$
$${v}_{z} = - \frac{K}{μ} ( \frac{\partial p}{\partial z} + ρ g ) ;$$
where v is a gas seepage velocity in unit of m/s; K is a formation permeability in unit of D; μ is a gas viscosity in unit of mPa·s; g is a gravity acceleration in unit of g/cm³; x, y and z are space coordinate axes;
when the gas seepage velocity increases beyond a predetermined value, there is a nonlinear relationship between a seepage velocity and a pressure gradient, which does not satisfy the Darcy's seepage law; in horizontal direction, when there is turbulence and inertia resistance in a process of gas seepage, a nonlinear quadratic equation of motion satisfying dynamic law of the natural gas is:
$$\frac{dp}{dx} = - ( \frac{μ}{K} v + ζρ {v}^{2} ) ;$$
where ξ is a characteristic parameter of a pore structure which influences the turbulence and the inertial resistance;
when the seepage velocity increases to deviate from the Darcy's law, the Darcy's law becomes:
$$v = - δ \frac{K}{μ} \frac{dp}{dx} ;$$
$$wherein$$
$$δ = \frac{1}{( 1 + ζρ Kv / μ )} ;$$
wherein δ is a turbulence correction coefficient;
in process of joint exploitation of hydrate, shallow gas and deep-seated gas, calculation equations of a water phase relative permeability k_{rw}, a gas phase relative permeability k_{rg} and a capillary pressure P_{c} are respectively:
$${k}_{rw} = {k}_{rw 0} {{\overline{{S}_{w}}}^{1 / 2} [ 1 - {( 1 - {\overline{{S}_{w}}}^{1 / m} )}^{m} ]}^{2} ;$$
$${k}_{rg} = {k}_{rg 0} {{\overline{{S}_{g}}}^{1 / 2} [ 1 - {\overline{{S}_{wh}}}^{1 / m} ]}^{m} ;$$
$${P}_{c} = {{P}_{c 0} [ {\overline{{S}_{w}}}^{1 / m} - 1 ]}^{1 - m} ;$$
$$where$$
$$\overline{{S}_{w}} = ( {S}_{w} - {S}_{wr} ) / ( 1 - {S}_{wr} - {S}_{gr} ) ;$$
$$\overline{{S}_{wh}} = ( {S}_{w} + {S}_{h} - {S}_{wr} ) / ( 1 - {S}_{wr} - {S}_{gr} ) ;$$
where S_{wr} is a bound water saturation, S_{gr} is a residual gas saturation, k_{rw0} and k_{rg0} are endpoint values of permeability, P_{c0} is an endpoint value of the capillary pressure, and m is a van Genuchten parameter.
